(19) United States
(12) Patent Application Publication
(10) Pub. No.: US 2021/0066055 A1
(43) Pub. Date: Mar. 4, 2021

(54) APPARATUS AND METHOD FOR TREATING SUBSTRATE

(71) Applicant: SEMES CO., LTD., Cheonan-si (KR)

(72) Inventors: Jeong Seok KANG, Cheonan-si (KR); Young Hwan YANG, Suwon-si (KR); Soo Ryun NOH, Suwon-si (KR)

(73) Assignee: SEMES CO., LTD., Cheonan-si (KR)

(21) Appl. No.: 17/012,178

(22) Filed: Sep. 4, 2020

(30) Foreign Application Priority Data
Sep. 4, 2019 (KR) 10-2019-0109246

(51) Int. Cl. H01J 37/32; H01L 21/67; H01L 21/683; H01L 21/687; B08B 5/00; B08B 13/00

(52) U.S. Cl. CPC H01J 37/32862; H01L 21/67069; H01L 21/6831; H01L 21/68735; H01J 2237/334; H01J 37/32642; B08B 5/00; B08B 13/00; H01J 37/32449

(57) ABSTRACT

An apparatus for treating a substrate includes a chamber having a process space therein, a support unit that supports the substrate in the process space, a gas supply unit that supplies a process gas into the process space, and a plasma generation unit that generates plasma from the process gas. The support unit includes a support plate having the substrate placed thereon, a first ring that surrounds the substrate placed on the support plate, a second ring that is disposed under the first ring and that surrounds the support plate, and a gas supply member that supplies a gas above the first ring, and the gas supply member includes a gas line vertically formed through the first ring and the second ring.

### CROSS-REFERENCE TO RELATED APPLICATIONS

A claim for priority under 35 U.S.C. § 119 is made to Korean Patent Application No. 10-2019-0109246 filed on Sep. 4, 2019, in the Korean Intellectual Property Office, the entire contents of which are hereby incorporated by reference.

### BACKGROUND

Embodiments of the inventive concept described herein relate to an apparatus and method for treating a substrate, and more particularly, relate to a substrate treating apparatus and method for treating a substrate using plasma.

Semiconductor manufacturing processes may include a process of treating a substrate using plasma. For example, among the semiconductor manufacturing processes, an etching process may remove a thin film on the substrate using plasma.

A process of cleaning a chamber has to be performed to remove impurities in the chamber after the substrate located in the chamber is treated by using plasma. However, a surface of a focus ring may be etched by a process gas when the process of cleaning the chamber is performed.

### SUMMARY

Embodiments of the inventive concept provide a substrate treating apparatus and method for preventing a surface of a focus ring from being etched when a process of cleaning a chamber is performed.

According to an exemplary embodiment, an apparatus for treating a substrate includes a chamber having a process space therein, a support unit that supports the substrate in the process space, a gas supply unit that supplies a process gas into the process space, and a plasma generation unit that generates plasma from the process gas. The support unit includes a support plate having the substrate placed thereon, a first ring that surrounds the substrate placed on the support plate, a second ring that is disposed under the first ring and that surrounds the support plate, and a gas supply member that supplies a gas above the first ring, and the gas supply member includes a gas line vertically formed through the first ring and the second ring.

The gas supply member further may include a gas supply part that supplies the gas into the gas line and a gas regulator that adjusts an amount of the gas that is supplied into the gas line.

The gas supply part may supply a helium (He) gas to protect a surface of the first ring from the plasma when a process of cleaning the chamber is performed.

The gas supply part may supply a silicon tetrachloride (SiCl₄) gas to coat a surface of the first ring when a process of cleaning the chamber is performed.

The gas supply part may supply at least one of an oxygen (O₂) gas, a hexafluorocyclobutene (C₄F₆) gas, and an octafluorocyclobutane (C₄F₈) gas to improve process efficiency in an edge region of the substrate when a substrate treating process is performed in the chamber.

The second ring may have, on an upper surface thereof, a step portion protruding upward from a region in which the gas line is provided.

In a region in which the gas line is provided, a coupling member may be provided between the first ring and the second ring.

The coupling member may be an O-ring.

A bolting ring that fixes the first ring and the second ring and presses the O-ring may be provided on outer surfaces of the first ring and the second ring.

According to an exemplary embodiment, a method for treating a substrate using the apparatus of the inventive concept includes supplying a gas above the first ring through the gas line while a treatment process is performed by using a gas in a plasma state in the process space.

The treatment process may include a cleaning process of cleaning the chamber after the substrate is unloaded from the chamber.

A helium (He) gas may be supplied into the gas line to protect a surface of the first ring from plasma when the cleaning process is performed.

A silicon tetrachloride (SiCl₄) gas may be supplied into the gas line to coat a surface of the first ring when the cleaning process is performed.

The treatment process may be a process of treating the substrate in the process space by using plasma.

At least one of an oxygen (O₂) gas, a hexafluorocyclobutene (C₄F₆) gas, and an octafluorocyclobutane (C₄F₈) gas may be supplied into the gas line to improve process efficiency in an edge region of the substrate.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a sectional view illustrating a substrate treating apparatus according to an embodiment of the inventive concept;

FIG. 2 is a sectional view illustrating a support unit according to an embodiment of the inventive concept;

FIG. 3 is a plan view illustrating a first ring according to an embodiment of the inventive concept;

FIGS. 4 and 5 are sectional views illustrating support units according to various embodiments of the inventive concept; and

FIG. 6 is a flowchart illustrating a substrate treating method according to an embodiment of the inventive concept.

### DETAILED DESCRIPTION

Other advantages and features of the inventive concept, and implementation methods thereof will be clarified through the following embodiments to be described in detail with reference to the accompanying drawings. The inventive concept may, however, be embodied in different forms and should not be construed as being limited to the embodiments set forth herein. Rather, these embodiments are provided so that the inventive concept is thorough and complete and fully conveys the scope of the inventive concept to a person skilled in the art to which the inventive concept pertains. Further, the inventive concept is only defined by the appended claims.

Even though not defined, all terms used herein (including technical or scientific terms) have the same meanings as those generally accepted by general technologies in the related art to which the inventive concept pertains. The terms defined in general dictionaries may be construed as having the same meanings as those used in the related art and/or a text of the present application and even when some terms are not clearly defined, they should not be construed as being conceptual or excessively formal.

Terms used herein are only for description of embodiments and are not intended to limit the inventive concept. As used herein, the singular forms are intended to include the plural forms as well, unless context clearly indicates otherwise. It will be further understood that the terms “comprise” and/or “comprising” used herein specify the presence of stated features or components, but do not preclude the presence or addition of one or more other features or components. In the specification, the term “and/or” indicates each of listed components or various combinations thereof.

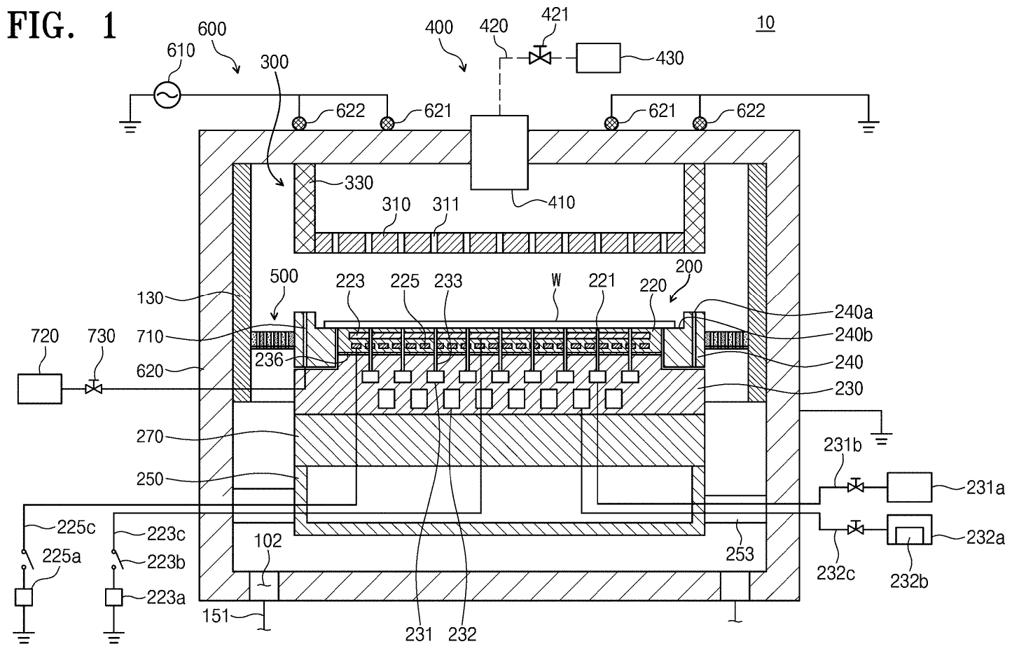

FIG. 1 is a sectional view illustrating a substrate treating apparatus according to an embodiment of the inventive concept.

Referring to FIG. 1, the substrate treating apparatus 10 treats a substrate W using plasma. For example, the substrate treating apparatus 10 may perform an etching process on the substrate W. The substrate treating apparatus 10 may include a chamber 620, a substrate support assembly 200, a showerhead 300, a gas supply unit 400, an exhaust baffle 500, and a plasma generation unit 600.

The chamber 620 may have a process space therein in which a substrate treating process is performed. The chamber 620 may have the process space therein and may be provided in an enclosed shape. The chamber 620 may be formed of a metallic material. The chamber 620 may be formed of an aluminum material. The chamber 620 may be grounded. The chamber 620 may have an exhaust hole 102 formed in the bottom thereof. The exhaust hole 102 may be connected with an exhaust line 151. Reaction byproducts generated in the substrate treating process and gases staying in the interior space of the chamber 620 may be released to the outside through the exhaust line 151. The pressure in the chamber 620 may be reduced to a predetermined pressure by the exhaust process.

According to an embodiment, a liner 130 may be provided in the chamber 620. The liner 130 may have a cylindrical shape that is open at the top and the bottom. The liner 130 may make contact with an inner surface of the chamber 620. The liner 130 may protect an inner wall of the chamber 620 to prevent the inner wall of the chamber 620 from being damaged by arc discharge. Furthermore, the liner 130 may prevent impurities generated during the substrate treating process from being deposited on the inner wall of the chamber 620. Selectively, the liner 130 may not be provided.

The substrate support assembly 200 may be located in the chamber 620. The substrate support assembly 200 may support the substrate W. The substrate support assembly 200 may include an electrostatic chuck 210 that clamps the substrate W using an electrostatic force. Alternatively, the substrate support assembly 200 may support the substrate W in various manners such as mechanical clamping. Hereinafter, the substrate support assembly 200 including the electrostatic chuck 210 will be described.

The substrate support assembly 200 may include the electrostatic chuck 210, a lower cover 250, and a plate 270. In the chamber 620, the substrate support assembly 200 may be located to be spaced apart upward from the bottom of the chamber 620.

The electrostatic chuck 210 may include a dielectric plate 220, a body 230, and an edge ring 240. The electrostatic chuck 210 may support the substrate W. The dielectric plate 220 may be located at the top of the electrostatic chuck 210. The dielectric plate 220 may be formed of a dielectric substance in a circular plate shape. The substrate W may be placed on an upper surface of the dielectric plate 220. The upper surface of the dielectric plate 220 may have a smaller radius than the substrate W. Due to this, an edge region of the substrate W may be located outside the dielectric plate 220.

The dielectric plate 220 may include a first electrode 223, a heating unit 225, and a first supply passage 221 inside. The first supply passage 221 may extend from the upper surface of the dielectric plate 210 to a lower surface thereof. A plurality of first supply passages 221 may be formed to be spaced apart from each other and may serve as passages through which a heat transfer medium is supplied to a bottom surface of the substrate W.

The first electrode 223 may be electrically connected with a first power source 223a. The first power source 223a may include a direct current (DC) power source. A switch 223b may be installed between the first electrode 223 and the first power source 223a. The first electrode 223 may be electrically connected with the first power source 223a by turning on/off the switch 223b. When the switch 223b is turned on, DC current may be applied to the first electrode 223. An electrostatic force may act between the first electrode 223 and the substrate W by the current applied to the first electrode 223, and the substrate W may be clamped to the dielectric plate 220 by the electrostatic force.

The heating unit 225 may be located under the first electrode 223. The heating unit 225 may be electrically connected with a second power source 225a. The heating unit 225 may generate heat by resisting electric current applied by the second power source 225a. The generated heat may be transferred to the substrate W through the dielectric plate 220. The substrate W may be maintained at a predetermined temperature by the heat generated from the heating unit 225. The heating unit 225 may include a spiral coil.

The body 230 may be located under the dielectric plate 220. The lower surface of the dielectric plate 220 and an upper surface of the body 230 may be bonded together by an adhesive 236. The body 230 may be formed of an aluminum material. A central region of the upper surface of the body 230 may be located in a higher position than an edge region of the upper surface of the body 230. The central region of the upper surface of the body 230 may have an area corresponding to the lower surface of the dielectric plate 220 and may be bonded to the lower surface of the dielectric plate 220. The body 230 may have a first circulation passage 231, a second circulation passage 232, and a second supply passage 233 formed therein.

The first circulation passage 231 may serve as a passage through which the heat transfer medium circulates. The first circulation passage 231 may be formed in a spiral shape inside the body 230. Alternatively, the first circulation passage 231 may be implemented with ring-shaped passages that have different radii and that are concentric with one another. The first circulation passages 231 may be connected together. The first circulation passages 231 may be formed at the same height.

The second circulation passage 232 may serve as a passage through which a cooling fluid circulates. The second circulation passage 232 may be formed in a spiral shape in the body 230. Alternatively, the second circulation passage 232 may be implemented with ring-shaped passages that have different radii and that are concentric with one another. The second circulation passages 232 may be connected together. The second circulation passages 232 may have a larger cross-sectional area than the first circulation passages 231. The second circulation passages 232 may be formed at the same height. The second circulation passages 232 may be located under the first circulation passages 231.

The second supply passage 233 may extend upward from the first circulation passages 231 to the upper surface of the body 230. As many second supply passages 233 as the first supply passages 221 may be provided, and the second supply passages 233 may connect the first circulation passages 231 and the first supply passages 221.

The first circulation passages 231 may be connected with a heat transfer medium reservoir 231a through a heat transfer medium supply line 231b. The heat transfer medium may be stored in the heat transfer medium reservoir 231a.

The heat transfer medium may include an inert gas. According to an embodiment, the heat transfer medium may include a helium (He) gas. The helium gas may be supplied into the first circulation passages 231 through the heat transfer medium supply line 231b and may be supplied to the bottom surface of the substrate W via the second supply passages 233 and the first supply passages 221. The helium gas may serve as a medium through which heat transferred from plasma to the substrate W is transferred to the electrostatic chuck 210.

The second circulation passages 232 may be connected with a cooling fluid reservoir 232a through a cooling fluid supply line 232c. The cooling fluid may be stored in the cooling fluid reservoir 232a. The cooling fluid reservoir 232a may include a cooler 232b therein. The cooler 232b may cool the cooling fluid to a predetermined temperature. Alternatively, the cooler 232b may be provided on the cooling fluid supply line 232c. The cooling fluid supplied into the second circulation passages 232 through the cooling fluid supply line 232c may cool the body 230 while circulating along the second circulation passages 232. The body 230, while being cooled, may cool the dielectric plate 220 and the substrate W together to maintain the substrate W at a predetermined temperature.

The body 230 may include a metal plate. According to an embodiment, the entire body 230 may be implemented with a metal plate.

The edge ring 240 may be disposed on an edge region of the electrostatic chuck 210. The edge ring 240 may have a ring shape and may be disposed around the dielectric plate 220. An outer portion 240a of an upper surface of the edge ring 240 may be located in a higher position than an inner portion 240b of the upper surface of the edge ring 240. The inner portion 240b of the upper surface of the edge ring 240 may be located in a lower position than the upper surface of the dielectric plate 220. The inner portion 240b of the upper surface of the edge ring 240 may support the edge region of the substrate W that is located outside the dielectric plate 220. The outer portion 240a of the edge ring 240 may surround the edge region of the substrate W. The edge ring 240 may control an electromagnetic field such that plasma density is uniformly distributed in the entire region of the substrate W.

Accordingly, plasma may be uniformly formed over the entire region of the substrate W, and thus each region of the substrate W may be uniformly etched.

The lower cover 250 may be located at the bottom of the substrate support assembly 200. The lower cover 250 may be located to be spaced apart upward from the bottom of the chamber 620. The lower cover 250 may have a space 255 formed therein, which is open at the top. The outer radius of the lower cover 250 may be equal to the outer radius of the body 230. A lift pin module (not illustrated) that moves the transferred substrate W from an external transfer member to the electrostatic chuck 210 may be located in the interior space 255 of the lower cover 250. The lift pin module (not illustrated) may be located to be spaced apart from the lower cover 250 at a predetermined interval. The bottom of the lower cover 250 may be formed of a metallic material. The lower cover 250 may have air in the interior space 255 thereof. The air may serve to decrease an electromagnetic field in the substrate support assembly 200 because the air has a lower permittivity than an insulator.

The lower cover 250 may have a connecting member 253. The connecting member 253 may connect an outer surface of the lower cover 250 and the inner wall of the chamber 620. A plurality of connecting members 253 may be provided at predetermined intervals on the outer surface of the lower cover 250. The connecting members 253 may support the substrate support assembly 200 in the chamber 620. Furthermore, the connecting members 253 may be connected with the inner wall of the chamber 620 to allow the lower cover 250 to be electrically grounded. A first power line 223c connected with the first power source 223a, a second power line 225c connected with the second power source 225a, the heat transfer medium supply line 231b connected with the heat transfer medium reservoir 231a, and the cooling fluid supply line 232c connected with the cooling fluid reservoir 232a may extend into the lower cover 250 through interior spaces of the connecting members 253.

The plate 270 may be located between the electrostatic chuck 210 and the lower cover 250. The plate 270 may cover the open top side of the lower cover 250. The plate 270 may have a cross-sectional area corresponding to the body 230. The plate 270 may include an insulator. According to an embodiment, one or more plates 270 may be provided. The plates 270 may serve to increase an electrical distance between the body 230 and the lower cover 250.

The showerhead 300 may be located over the substrate support assembly 200 in the chamber 620. The showerhead 300 may be located to face the substrate support assembly 200.

The showerhead 300 may include a gas distribution plate 310 and a support part 330. The gas distribution plate 310 may be located to be spaced apart downward from the top of the chamber 620 by a predetermined distance. A predetermined space may be formed between the gas distribution plate 310 and the top of the chamber 620. The gas distribution plate 310 may be provided in a plate shape having a constant thickness. A bottom surface of the gas distribution plate 310 may be anodized to prevent an electric arc caused by plasma. A section of the gas distribution plate 310 may have the same shape and cross-sectional area as the substrate support assembly 200. The gas distribution plate 310 may include a plurality of injection holes 311. The injection holes 311 may be formed through the gas distribution plate 310 in the vertical direction. The gas distribution plate 310 may contain a metallic material.

The support part 330 may support a lateral portion of the gas distribution plate 310. The support part 330 may be connected, at an upper end thereof, with the top of the chamber 620 and may be connected, at a lower end thereof, with the lateral portion of the gas distribution plate 310. The support part 330 may contain a non-metallic material.

The gas supply unit 400 may supply a process gas into the chamber 620. The gas supply unit 400 may include a gas supply nozzle 410, a gas supply line 420, and a gas reservoir 430. The gas supply nozzle 410 may be installed in a central portion of the top of the chamber 620. The gas supply nozzle 410 may have an injection hole formed in a bottom surface thereof. The injection hole may supply the process gas into the chamber 620. The gas supply line 420 may connect the gas supply nozzle 410 and the gas reservoir 430. The gas supply line 420 may supply the process gas stored in the gas reservoir 430 to the gas supply nozzle 410. A valve 421 may be provided in the gas supply line 420. The valve 421 may open or close the gas supply line 420 and may regulate the flow rate of the process gas that is supplied through the gas supply line 420.

The exhaust baffle 500 may be located between the inner wall of the chamber 620 and the substrate support assembly 200. The exhaust baffle 500 may have an annular ring shape. The exhaust baffle 500 may have a plurality of through-holes formed therein. The process gas supplied into the chamber 620 may pass through the through-holes of the exhaust baffle 500 and may be released through the exhaust hole 102. A flow of the process gas may be controlled depending on the shape of the exhaust baffle 500 and the shape of the through-holes.

The plasma generation unit 600 may excite the process gas in the chamber 620 into a plasma state. According to an embodiment of the inventive concept, the plasma generation unit 600 may be implemented in an inductively coupled plasma (ICP) type. In this case, as illustrated in FIG. 1, the plasma generation unit 600 may include an RF power source 610 that supplies RF power, and a first coil 621 and a second coil 622 that are electrically connected to the RF power source 610 and that receive the RF power from the RF power source 610.

In this specification, it has been described that the plasma generation unit 600 is of an inductively coupled plasma (ICP) type. Without being limited thereto, however, the plasma generation unit 600 may be implemented in a capacitively coupled plasma (CCP) type.

In a case where a CCP type plasma source is used, an upper electrode and a lower electrode, that is, a body may be included in the chamber 620. The upper electrode and the lower electrode may be vertically disposed parallel to each other with a process space therebetween. Not only the lower electrode but also the upper electrode may receive energy for generation of plasma by being supplied with an RF signal by an RF power source, and the number of RF signals applied to each electrode is not limited to one as illustrated. An electric field may be formed in a space between the two electrodes, and a process gas supplied into the space may be excited into a plasma state. A substrate treating process is performed by using the plasma.

Referring again to FIG. 1, the first coil 621 and the second coil 622 may be disposed in positions facing the substrate W. For example, the first coil 621 and the second coil 622 may be provided on the top of the chamber 620. The first coil 621 may have a smaller diameter than the second coil 622 and may be located on an inner portion of the top of the chamber 620, and the second coil 622 may be located on an outer portion of the top of the chamber 620. The first coil 621 and the second coil 622 may receive RF power from the RF power source 610 and may induce a time varying magnetic field in the chamber 620. Accordingly, the process gas supplied into the chamber 620 may be excited into plasma.

Hereinafter, a process of treating a substrate using the above-described substrate treating apparatus 10 will be described.

When the substrate W is placed on the substrate support assembly 200, DC current may be applied from the first power source 233a to the first electrode 223. An electrostatic force may act between the first electrode 223 and the substrate W by the DC current applied to the first electrode 223, and the substrate W may be clamped to the electrostatic chuck 210 by the electrostatic force.

When the substrate W is clamped to the electrostatic chuck 210, the process gas may be supplied into the chamber 620 through the gas supply nozzle 410. The process gas may be uniformly injected into the chamber 620 through the injection holes 311 of the showerhead 300. RF power generated by the RF power source 610 may be applied to the plasma source. Due to this, an electromagnetic force may be generated in the chamber 620. The electromagnetic force may excite the process gas between the substrate support assembly 200 and the showerhead 300 into plasma. The plasma may be supplied to the substrate W to treat the substrate W. The plasma may be used to perform an etching process.

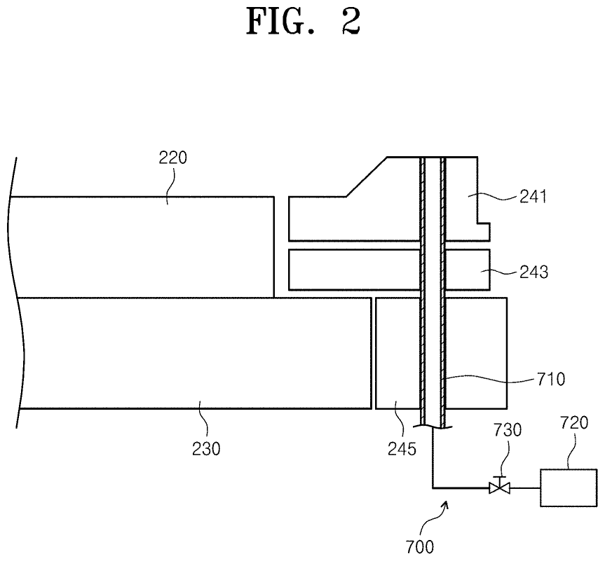

FIG. 2 is a sectional view illustrating a support unit according to an embodiment of the inventive concept.

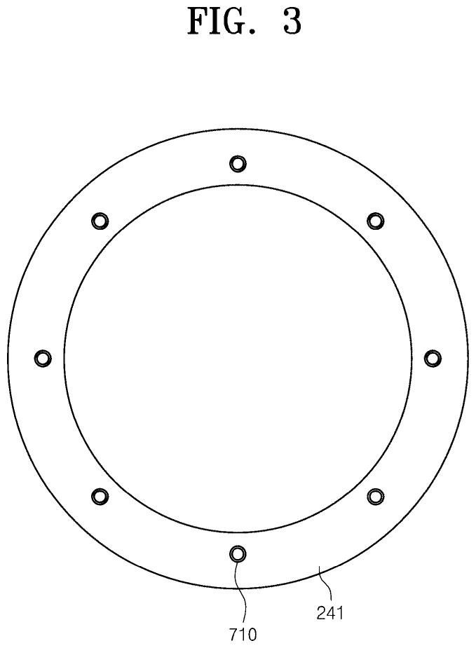

Referring to FIG. 2, the support unit may include the dielectric plate 220, the body 230, a first ring 241, a second ring 243, an insulating ring 245, and a gas supply member 700. The first ring 241 surrounds a substrate placed on the dielectric plate 220. For example, the first ring 241 may be referred to as a focus ring. The first ring 241 may be formed of a metallic material. Under the first ring 241, the second ring 243 surrounds the dielectric plate 220. For example, the second ring 243 may be referred to as an insert ring. The second ring 243 may be formed of a metallic material. The insulating ring 245 may be formed of an insulating material and may electrically insulate the first ring 241 and the second ring 243 from modules under the electrostatic chuck 210. The gas supply member 700 may supply a gas above the first ring 241. The gas supply member 700 may include a gas line 710, a gas supply part 720, and a gas regulator 730. The gas line 710 may vertically pass through the first ring 241, the second ring 243, and the insulating ring 245. Referring to FIG. 3, the gas line 710 may be provided in a plurality of regions of the first ring 241. When viewed from above the first ring 241, holes may be formed in the plurality of regions of the first ring 241, and the gas line 710 may be provided in each of the holes. The gas supply part 720 may supply the gas into the gas line 710, and the gas regulator 730 may adjust the amount of the gas that is supplied into the gas line 710. When a process of cleaning the chamber 620 is performed, the gas supply part 720 may supply a helium (He) gas to protect a surface of the first ring 241 from plasma. That is, when the process of cleaning the chamber 620 is performed, the helium gas may be supplied to the surface of the first ring 241 to prevent a cleaning gas in a plasma state from etching the surface of the first ring 241. Furthermore, when the process of cleaning the chamber 620 is performed, the gas supply part 720 may supply a silicon tetrachloride (SiCl₄) gas to coat the surface of the first ring 241. Accordingly, when the process of cleaning the chamber 620 is performed, the surface of the first ring 241 may be prevented from being etched, and in a substrate treating process after the process of cleaning the chamber 620, the surface of the first ring 241 may be prevented from being etched. When the substrate treating process is performed in the chamber 620, the gas supply part 720 may supply at least one of an oxygen (O₂) gas, a hexafluorocyclobutene (C₄F₆) gas, and an octafluorocyclobutane (C₄F₈) gas to improve process efficiency in an edge region of the substrate. Specifically, in the substrate treating process, a gas required for the process may be unevenly supplied to the edge region of the substrate, and therefore process efficiency may be deteriorated. However, the inventive concept may improve process efficiency by additionally supplying the gas required for the process to the surface of the first ring 241 through the gas line 710.

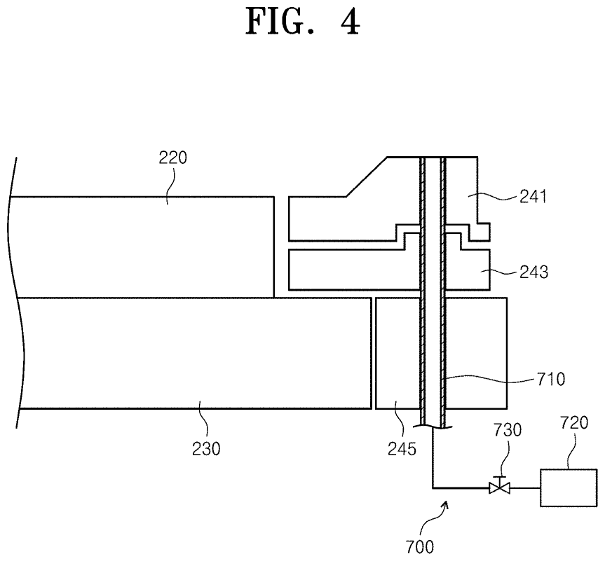

Referring to FIG. 4, the second ring 243 may have, on an upper surface thereof, a step portion protruding upward from a region in which the gas line 710 is provided. Accordingly, the first ring 241 and the second ring 243 may be firmly fixed, and gas leakage may be prevented.

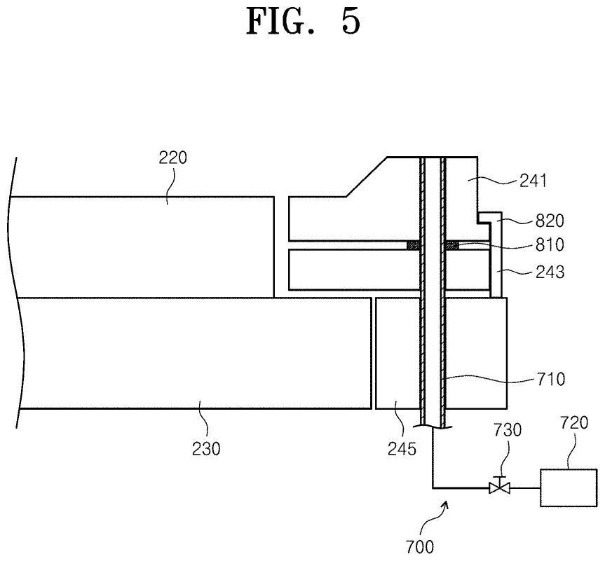

Referring to FIG. 5, in the region in which the gas line 710 is provided, a coupling member 810 may be provided between the first ring 241 and the second ring 243. For example, the coupling member 810 may be an O-ring. A bolting ring 820 may be provided on outer surfaces of the first ring 241 and the second ring 243. The bolting ring 820 may fix the first ring 241 and the second ring 243 and may press the O-ring. Accordingly, the first ring 241 and the second ring 243 may be more firmly coupled together, and gas leakage from the gas line 710 may be prevented.

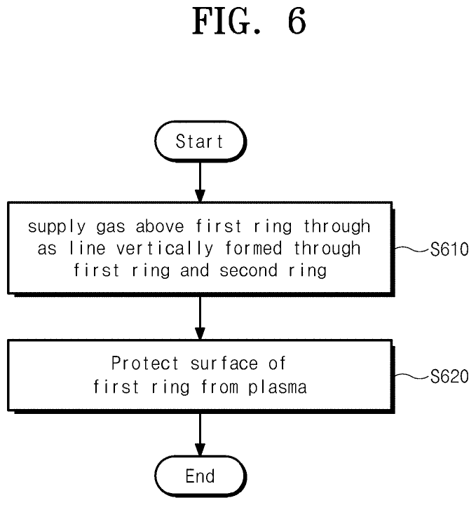

FIG. 6 is a flowchart illustrating a substrate treating method according to an embodiment of the inventive concept.

Referring to FIG. 6, while a treatment process is performed by using a gas in a plasma state in the process space of the chamber 620, a gas may be supplied above the first ring 241 through the gas line 710 vertically formed through the first ring 241 and the second ring 243 (S610). Accordingly, the surface of the first ring 241 may be protected from plasma (S620). Here, the treatment process may include a cleaning process of cleaning the chamber 620 after a substrate is unloaded from the chamber 620. Furthermore, when the cleaning process is performed, a helium (He) gas may be supplied into the gas line 710 to protect the surface of the first ring 241 from plasma, or a silicon tetrachloride (SiCl₄) gas may be supplied into the gas line 710 to coat the surface of the first ring 241. In addition, when the substrate is treated by using plasma, at least one of an oxygen (O₂) gas, a hexafluorocyclobutene (C₄F₆) gas, and an octafluorocyclobutane (C₄F₈) gas may be supplied into the gas line 710 to improve process efficiency in the edge region of the substrate.

According to the various embodiments of the inventive concept, when the chamber 620 is cleaned, the surface of the focus ring may be prevented from being etched, and when the substrate is treated by using plasma, process efficiency in the edge region of the substrate may be improved.

As described above, according to the various embodiments of the inventive concept, the substrate treating apparatus and method may prevent a surface of a focus ring from being etched when a chamber is cleaned.

In addition, the inventive concept may improve process efficiency in an edge region of a substrate when the substrate is treated by using plasma.

Although the embodiments of the inventive concept have been described above, it should be understood that the embodiments are provided to help with comprehension of the inventive concept and are not intended to limit the scope of the inventive concept and that various modifications and equivalent embodiments can be made without departing from the spirit and scope of the inventive concept. For example, the components illustrated in the embodiments of the inventive concept can be implemented in a distributed manner. Likewise, the components described to be distributed can be implemented in a combined manner. Accordingly, the spirit and scope of the inventive concept should be determined by the technical idea of the claims, and it should be understood that the spirit and scope of the inventive concept is not limited to the literal description of the claims, but actually extends to the category of equivalents of technical value.

While the inventive concept has been described with reference to exemplary embodiments, it will be apparent to those skilled in the art that various changes and modifications may be made without departing from the spirit and scope of the inventive concept. Therefore, it should be understood that the above embodiments are not limiting, but illustrative.

1. An apparatus for treating a substrate, the apparatus comprising:
a chamber having a process space therein;
a support unit configured to support the substrate in the process space;
a gas supply unit configured to supply a process gas into the process space; and
a plasma generation unit configured to generate plasma from the process gas,
wherein the support unit includes:
a support plate having the substrate placed thereon;
a first ring configured to surround the substrate placed on the support plate;
a second ring disposed under the first ring and configured to surround the support plate; and
a gas supply member configured to supply a gas above the first ring, and
wherein the gas supply member includes a gas line vertically formed through the first ring and the second ring.

2. The apparatus of claim 1, wherein the gas supply member further includes:
a gas supply part configured to supply the gas into the gas line; and
a gas regulator configured to adjust an amount of the gas that is supplied into the gas line.

3. The apparatus of claim 2, wherein the gas supply part supplies a helium (He) gas to protect a surface of the first ring from the plasma when a process of cleaning the chamber is performed.

4. The apparatus of claim 2, wherein the gas supply part supplies a silicon tetrachloride (SiCl₄) gas to coat a surface of the first ring when a process of cleaning the chamber is performed.

5. The apparatus of claim 2, wherein the gas supply part supplies at least one of an oxygen (O₂) gas, a hexafluorocyclobutene (C₄F₆) gas, and an octafluorocyclobutane (C₄F₈) gas to improve process efficiency in an edge region of the substrate when a substrate treating process is performed in the chamber.

6. The apparatus of claim 1, wherein the second ring has, on an upper surface thereof, a step portion protruding upward from a region in which the gas line is provided.

7. The apparatus of claim 1, wherein in a region in which the gas line is provided, a coupling member is provided between the first ring and the second ring.

8. The apparatus of claim 7, wherein the coupling member is an O-ring.

9. The apparatus of claim 8, wherein a bolting ring configured to fix the first ring and the second ring and press the O-ring is provided on outer surfaces of the first ring and the second ring.

10. An apparatus for treating a substrate, the apparatus comprising:
a chamber having a process space therein; and
a support unit configured to support the substrate in the process space,
wherein the support unit includes:
a support plate having the substrate placed thereon;
a focus ring configured to surround the substrate placed on the support plate;
an insert ring disposed under the focus ring and configured to surround the support plate;
an insulating ring configured to insulate the focus ring and the insert ring; and
a gas line formed through the focus ring, the insert ring, and the insulating ring.

11. The apparatus of claim 10, further comprising:
a gas supply member configured to supply a gas above the focus ring through the gas line.

12. The apparatus of claim 11, wherein the gas is at least one of a helium gas, a silicon tetrachloride (SiCl₄) gas, an oxygen (O₂) gas, a hexafluorocyclobutene (C₄F₆) gas, and an octafluorocyclobutane (C₄F₈) gas.

13.-18. (canceled)
